(19) United States
(12) Patent Application Publication
(10) Pub. No.: US 2007/0221332 A1
(43) Pub. Date: Sep. 27, 2007

(54) PLASMA PROCESSING APPARATUS

(75) Inventors: Masanobu HONDA, Nirasaki-shi (JP); Yutaka Matsui, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/686,618

(22) Filed: Mar. 15, 2007

Related U.S. Application Data
(60) Provisional application No. 60/788,088, filed on Apr. 3, 2006.

(30) Foreign Application Priority Data
Mar. 22, 2006 (JP) 2006-079639

(51) Int. Cl. C23F 1/00; C23C 16/00

(52) U.S. Cl. 156/345.47; 118/723 E

(57) ABSTRACT

A plasma processing apparatus which enables an insulating film on a grounding electrode to be removed. A plasma processing apparatus has a substrate processing chamber having therein a processing space in which plasma processing is carried out on a substrate, an RF electrode that applies radio frequency electrical power into the processing space, a DC electrode that applies a DC voltage into the processing space, and a grounding electrode that is exposed to the processing space. The grounding electrode and the RF electrode are adjacent to one another with an insulating portion therebetween, and a distance between the grounding electrode and the RF electrode is set in a range of 0 to 10 mm.

### BACKGROUND OF THE INVENTION

1. Field of the Invention

The present invention relates to a plasma processing apparatus, and in particular relates to a plasma processing apparatus having therein an electrode that is connected to a DC power source.

2. Description of Related Art

Parallel plate type plasma processing apparatuses are known that have a substrate processing chamber having therein a processing space into which is transferred a wafer as a substrate, a lower electrode that is disposed in the substrate processing chamber and is connected to a radio frequency power source, and an upper electrode that is disposed such as face the lower electrode. In such a plasma processing apparatus, a processing gas is introduced into the processing space, and radio frequency electrical power is applied into the processing space between the upper electrode and the lower electrode. When a wafer has been transferred into the processing space and mounted on the lower electrode, the introduced processing gas is turned into plasma through the radio frequency electrical power so as to produce ions and so on, and the wafer is subjected to plasma processing, for example etching processing, by the ions and so on.

In recent years, with an aim of improving the plasma processing performance, plasma processing apparatuses in which the upper electrode is connected to a DC power source so that a DC voltage is applied into the processing space have been developed. To apply the DC voltage into the processing space, an electrode at ground potential (hereinafter referred to as the “grounding electrode”) having a conductive surface thereof exposed to the processing space must be provided. However, in the case of carrying out the plasma processing using a deposit-forming processing gas, deposit may become attached to the surface of the grounding electrode so that a deposit film is formed thereon. Moreover, depending on the type of the processing gas, the surface of the grounding electrode may become covered with an oxide film or nitride film. Such a deposit film, oxide film, or nitride film is insulating, and hence the DC current flow from the upper electrode to the grounding electrode is impeded, so that the DC voltage can no longer be applied into the processing space. It is thus necessary to remove such a deposit film or the like.

Conventionally, as a method of removing a deposit film or the like from an electrode surface, there has been known a method in which oxygen (O₂) gas is introduced into the processing space, and oxygen ions and oxygen radicals are produced from the oxygen gas, so that the deposit film or the like is removed through reaction with the oxygen ions and oxygen radicals (see, for example, Japanese Laid-open Patent Publication (Kokai) No. S62-040728).

For the above method of removing a deposit film or the like, processing separate to the wafer plasma processing must be carried out, and hence the productivity of production of semiconductor devices from the wafers decreases. There has thus been developed a method of removing a deposit film or the like during the wafer plasma processing, specifically a deposit film removal method in which radio frequency electrical power of a relatively low frequency, for example 2 MHz, is transmitted to components inside the substrate processing chamber including the grounding electrode. In this deposit film removal method, a fluctuating potential is produced on the surface of the grounding electrode due to the 2 MHz radio frequency electrical power. At this time, positive ions are able to follow the fluctuating potential of the relatively low frequency, and hence the positive ions are drawn onto the grounding electrode through the fluctuating potential so that the surface of the grounding electrode is sputtered. As a result, the deposit film or the like is removed.

However, there are cases in which such radio frequency electrical power of a relatively low frequency cannot be supplied in during the plasma processing, for example cases in which it is desired to allow only radicals to contact the wafer. In such a case, radio frequency electrical power of a relatively high frequency is transmitted to the grounding electrode and so on, but positive ions cannot follow a fluctuating potential of such a relatively high frequency, and hence the potential difference for the fluctuating potential produced due to the radio frequency electrical power of the relatively high frequency is small. Positive ions are thus drawn onto the grounding electrode with low energy, and hence the deposit film or the like cannot be removed.

### SUMMARY OF THE INVENTION

It is an object of the present invention to provide a plasma processing apparatus that enables an insulating film on a grounding electrode to be removed.

To attain the above object, in a first aspect of the present invention, there is provided a plasma processing apparatus that has a substrate processing chamber having therein a processing space in which plasma processing is carried out on a substrate, an RF electrode that applies radio frequency electrical power into the processing space, a DC electrode that applies a DC voltage into the processing space, and a grounding electrode that is exposed to the processing space, wherein the grounding electrode and the RF electrode are adjacent to one another with an insulating portion therebetween, and a distance between the grounding electrode and the RF electrode is set in a range of 0 to 10 mm.

According to the above construction, the radio frequency electrical power applied by the RF electrode not only produces an electric field in a portion of the processing space facing the RF electrode, but also produces an electric field having a predetermined strength in a portion of the processing space in the vicinity of the RF electrode. Moreover, the electric field almost dies out beyond 10 mm from the RF electrode. As a result, an electric field having a predetermined strength is produced in a portion of the processing space facing the grounding electrode, and hence ions collide with the grounding electrode due to a potential difference for the electric field. An insulating film on the grounding electrode can thus be removed.

Preferably, the distance is set in a range of 0 to 5 mm.

According to the above construction, the electric field having a predetermined strength can be produced reliably in the portion of the processing space facing the grounding electrode, and hence the insulating film on the grounding electrode can be removed reliably.

Preferably, a lower limit of the distance is 0.5 mm.

According to the above construction, the lower limit of the distance between the grounding electrode and the RF electrode is 0.5 mm. As a result, the radio frequency electrical power can be prevented from being applied to the grounding electrode with margin to spare. The grounding electrode can thus be kept at ground potential, and hence the DC voltage can be reliably applied into the processing space.

Preferably, the insulating portion comprises an insulator or a vacuum space.

According to the above construction, the radio frequency electrical power can be reliably prevented from being applied to the grounding electrode.

To attain the above object, in a second aspect of the present invention, there is provided a plasma processing apparatus that has a substrate processing chamber having therein a processing space in which plasma processing is carried out on a substrate, an RF electrode that applies only radio frequency electrical power of not less than a predetermined frequency into the processing space, a DC electrode that applies a DC voltage into the processing space, and a grounding electrode that is exposed to the processing space, wherein the grounding electrode and the RF electrode are adjacent to one another with an insulating portion therebetween.

According to the above construction, only radio frequency electrical power of not less than a predetermined frequency is applied into the processing space. As a result, ions cannot readily follow a fluctuating potential produced due to the radio frequency electrical power, and hence an insulating film on the grounding electrode cannot be removed through ions being drawn in thereto due to such a fluctuating potential. However, the radio frequency electrical power applied by the RF electrode not only produces an electric field in a portion of the processing space facing the RF electrode, but also produces an electric field having a predetermined strength in a portion of the processing space in the vicinity of the RF electrode. As a result, an electric field having a predetermined strength is produced in a portion of the processing space facing the grounding electrode, and hence ions collide with the grounding electrode due to a potential difference for the electric field. The insulating film on the grounding electrode can thus be removed.

Preferably, the predetermined frequency is 13 MHz.

According to the above construction, although ions will not follow a fluctuating potential produced due to the radio frequency electrical power, an electric field having a predetermined strength is produced in a portion of the processing space facing the grounding electrode, and hence ions can be reliably drawn onto the grounding electrode through the electric field.

Preferably, the insulating portion comprises an insulator or a vacuum space.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate an embodiment of the present invention and, together with the description, serve to explain the principles of the present invention.

FIG. 1 is a sectional view schematically showing the construction of a plasma processing apparatus according to a first embodiment of the present invention;

FIG. 2 is a sectional view schematically showing the construction of a conventional plasma processing apparatus;

FIG. 3 is a graph showing the relationship between a deposit attachment rate and locations on components in the case of supplying only 60 MHz radio frequency electrical power to an upper electrode plate;

FIG. 4 is a graph showing the relationship between the electric field strength calculated through simulation and locations on the components in the case of supplying only the 60 MHz radio frequency electrical power to the upper electrode plate; and

FIG. 5 is a sectional view schematically showing the construction of a plasma processing apparatus according to a second embodiment of the present invention.

### DETAILED DESCRIPTION OF PREFERRED EMBODIMENT

Preferred embodiments of the present invention will be described in detail below with reference to the drawings.

First, a plasma processing apparatus according to a first embodiment of the present invention will be described.

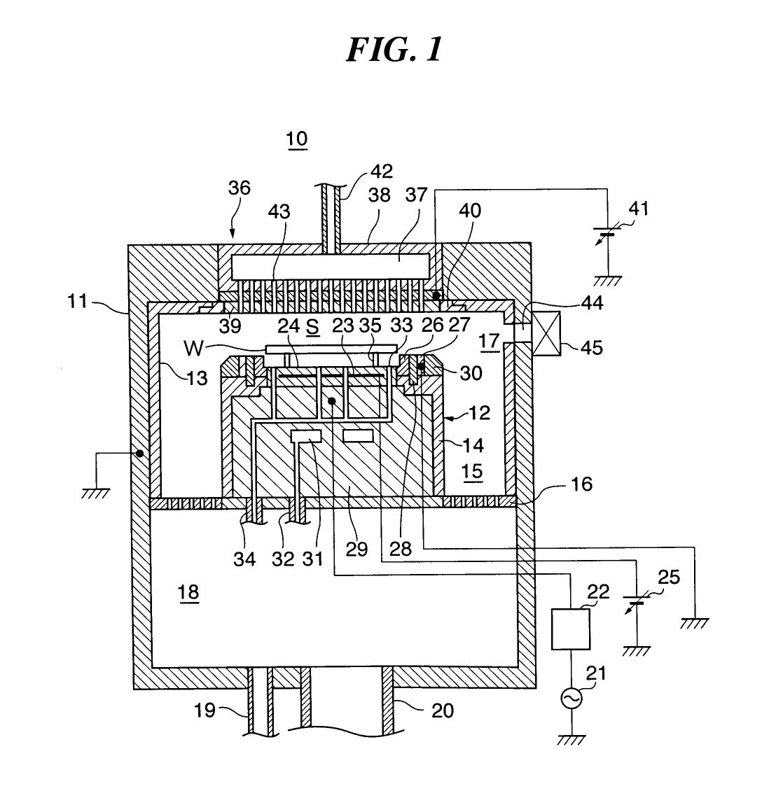

FIG. 1 is a sectional view schematically showing the construction of the plasma processing apparatus according to the present embodiment. The plasma processing apparatus is constructed such as to carry out RIE (reactive ion etching) processing on a semiconductor wafer W as a substrate.

As shown in FIG. 1, the plasma processing apparatus 10 has a cylindrical substrate processing chamber 11, there being a processing space S inside the substrate processing chamber 11. Moreover, the substrate processing chamber 11 has disposed therein a cylindrical susceptor 12 (RF electrode) as a stage on which is mounted a semiconductor wafer W (hereinafter referred to merely as a “wafer W”) having a diameter of, for example, 300 mm. An inner wall surface of the substrate processing chamber 11 is covered by a side wall member 13. The side wall member 13 is made of aluminum, a surface thereof that faces the processing space S being coated with yttria (Y₂O₃). The substrate processing chamber 11 is electrically grounded, and hence the side wall member 13 is at ground potential. Moreover, the susceptor 12 has a conductor portion 29 made of a conductive material, for example aluminum, and a susceptor side face covering member 14 made of an insulating material covering a side face of the conductor portion 29.

In the plasma processing apparatus 10, an exhaust flow path 15 that acts as a flow path through which gas molecules above the susceptor 12 are exhausted out of the substrate processing chamber 11 is formed between an inner wall of the substrate processing chamber 11 and the side face of the susceptor 12. A baffle plate 16 is disposed part way along the exhaust flow path 15.

The baffle plate 16 is a plate-shaped member having a large number of holes therein, and acts as a partitioning plate that partitions the substrate processing chamber 11 into an upper portion and a lower portion. Plasma, described below, is produced in the upper portion (hereinafter referred to as the “reaction chamber”) 17 of the substrate processing chamber 11 partitioned by the baffle plate 16. Moreover, a roughing exhaust pipe 19 and a main exhaust pipe 20 that exhaust gas out from the substrate processing chamber 11 are provided in the lower portion (hereinafter referred to as the “manifold”) 18 of the substrate processing chamber 11. The roughing exhaust pipe 19 has a DP (dry pump) (not shown) connected thereto, and the main exhaust pipe 20 has a TMP (turbo-molecular pump) (not shown) connected thereto. Moreover, the baffle plate 16 captures or reflects ions and radicals produced in the processing space S, thus preventing leakage of the ions and radicals into the manifold 18.

The roughing exhaust pipe 19, the main exhaust pipe 20, the DP, and the TMP together constitute an exhausting apparatus. The roughing exhaust pipe 19 and the main exhaust pipe 20 exhaust gas in the reaction chamber 17 out of the substrate processing chamber 11 via the manifold 18. Specifically, the roughing exhaust pipe 19 reduces the pressure in the substrate processing chamber 11 from atmospheric pressure down to a low vacuum state, and the main exhaust pipe 20 is operated in collaboration with the roughing exhaust pipe 19 to reduce the pressure in the substrate processing chamber 11 from atmospheric pressure down to a high vacuum state (e.g. a pressure of not more than 133 Pa (1 Torr)), which is at a lower pressure than the low vacuum state

A radio frequency power source 21 is connected to the conductor portion 29 of the susceptor 12 via a matcher 22. The radio frequency power source 21 supplies radio frequency electrical power of a relatively high frequency, for example 40 MHz, to the conductor portion 29. The conductor portion 29 of the susceptor 12 thus acts as an RF electrode. The matcher 22 reduces reflection of the radio frequency electrical power from the conductor portion 29 so as to maximize the efficiency of the supply of the radio frequency electrical power into the conductor portion 29. The susceptor 12 applies the 40 MHz radio frequency electrical power supplied from the radio frequency power source 21 into the processing space S.

During the RIE processing, an insulating film such as a deposit film, an oxide film, or a nitride film may be formed on a surface of the susceptor side face covering member 14, and on an exposed portion of a silicon electrode 27, described below. Here, a radio frequency (40 MHz) fluctuating potential is produced on the surface of the susceptor side face covering member 14 due to the 40 MHz radio frequency electrical power supplied to the conductor portion 29. However, positive ions cannot follow a potential difference fluctuating at 40 MHz, and hence the potential difference produced due to the 40 MHz radio frequency electrical power is small, and thus the energy of positive ions colliding with the susceptor side face covering member 14 is low. The insulating film formed on the surface of the susceptor side face covering member 14 is thus not removed through the 40 MHz fluctuating potential.

A disk-shaped electrostatic chuck 24 having an electrode plate 23 therein is provided in an upper portion of the susceptor 12. When a wafer W is mounted on the susceptor 12, the wafer W is disposed on the electrostatic chuck 24. A DC power source 25 is electrically connected to the electrode plate 23. Upon a negative DC voltage being applied to the electrode plate 23, a positive potential is produced on a rear surface of the wafer W. A potential difference thus arises between the electrode plate 23 and the rear surface of the wafer W, and hence the wafer W is attracted to and held on an upper surface of the electrostatic chuck 24 through a Coulomb force or a Johnsen-Rahbek force due to the potential difference.

An annular focus ring 26 is provided on an upper portion of the susceptor 12 so as to surround the wafer W attracted to and held on the upper surface of the susceptor 12. The focus ring 26 is made of silicon (Si) or silica (SiO₂). The focus ring 26 is exposed to the processing space S, and focuses plasma in the processing space S toward a front surface of the wafer W, thus improving the efficiency of the RIE processing. Moreover, the 40 MHz radio frequency electrical power supplied to the conductor portion 29 is transmitted to the focus ring 26 via the electrostatic chuck 24. Here, the focus ring 26 applies the 40 MHz radio frequency electrical power into the processing space S. The focus ring 26 thus also acts as an RF electrode.

The silicon electrode 27, which is annular and made of silicon, is disposed surrounding the focus ring 26 adjacent to the focus ring 26. The silicon electrode 27 has an exposed portion that is exposed to the processing space S, and moreover is electrically grounded and thus acts as a grounding electrode. Moreover, the silicon electrode 27 constitutes part of a path of a DC current due to a DC voltage applied into the processing space S by an upper electrode plate 39, described below.

An annular insulator ring 28 (insulating portion) made of an insulating material, for example quartz (Qz), is disposed between the focus ring 26 and the silicon electrode 27. Moreover, the susceptor side face covering member 14 is provided such as to be interposed between the silicon electrode 27 and the conductor portion 29 of the susceptor 12. The silicon electrode 27 is thus electrically insulated from the conductor portion 29 and the focus ring 26, the insulator ring 28 and the susceptor side face covering member 14 reliably preventing the radio frequency electrical power supplied to the conductor portion 29 and the focus ring 26 from being applied to the silicon electrode 27.

Moreover, an annular cover ring 30 made of quartz that protects a side face of the silicon electrode 27 is disposed surrounding the silicon electrode 27.

An annular coolant chamber 31 that extends, for example, in a circumferential direction of the susceptor 12 is provided inside the susceptor 12. A coolant, for example cooling water or a Galden® fluid, at a predetermined temperature is circulated through the coolant chamber 31 via coolant piping 32 from a chiller unit (not shown). A processing temperature of the wafer W attracted to and held on the upper surface of the susceptor 12 is controlled through the temperature of the coolant.

A plurality of heat transfer gas supply holes 33 are provided in a portion of the upper surface of the susceptor 12 on which the wafer W is attracted and held (hereinafter referred to as the “attracting surface”). The heat transfer gas supply holes 33 are connected to a heat transfer gas supply unit (not shown) by a heat transfer gas supply line 34 which is disposed inside the susceptor 12. The heat transfer gas supply unit supplies helium (He) gas as a heat transfer gas via the heat transfer gas supply holes 33 into a gap between the attracting surface of the susceptor 12 and the rear surface of the wafer W.

A plurality of pusher pins 35 are provided in the attracting surface of the susceptor 12 as lifting pins that can be made to project out from the upper surface of the susceptor 12. The pusher pins 35 are connected to a motor (not shown) by a ball screw (not shown), and can be made to project out from the attracting surface of the susceptor 12 through rotational motion of the motor, which is converted into linear motion by the ball screw. The pusher pins 35 are housed inside the susceptor 12 when a wafer W is being attracted to and held on the attracting surface of the susceptor 12 so that the wafer W can be subjected to the RIE processing, and are made to project out from the upper surface of the susceptor 12 so as to lift the wafer W up away from the susceptor 12 when the wafer W is to be transferred out from the substrate processing chamber 11 after having been subjected to the RIE processing.

A gas introducing shower head 36 is disposed in a ceiling portion of the substrate processing chamber 11 such as to face the susceptor 12. The gas introducing shower head 36 has an electrode plate support 38 made of an insulating material having a buffer chamber 37 formed therein, and the upper electrode plate 39 which is supported from the electrode plate support 38. A lower surface of the upper electrode plate 39 is exposed to the processing space S. The upper electrode plate 39 is a disk-shaped member made of a conductive material, for example silicon. A peripheral portion of the upper electrode plate 39 is covered by an annular shield ring 40 made of an insulating material. The upper electrode plate 39 is thus electrically insulated by the electrode plate support 38 and the shield ring 40 from the wall of the substrate processing chamber 11, which is at the ground potential.

A DC power source 41 is electrically connected to the upper electrode plate 39, and applies a negative DC voltage to the upper electrode plate 39. The upper electrode plate 39 thus applies a DC voltage into the processing space S. Because a DC voltage is applied to the upper electrode plate 39, there is no need to provide a matcher between the upper electrode plate 39 and the DC power source 41, and hence compared with the case that a radio frequency power source is connected to the upper electrode plate via a matcher as in a conventional plasma processing apparatus, the structure of the plasma processing apparatus 10 can be simplified. Moreover, the upper electrode plate 39 remains at a negative potential with no fluctuation, and hence can be kept in a state of drawing in only positive ions thereto, electrons thus not being lost from the processing space S. There is thus no reduction in the number of electrons in the processing space S, and hence the efficiency of the plasma processing such as RIE processing can be improved.

A processing gas introducing pipe 42 leading from a processing gas supply unit (not shown) is connected to the buffer chamber 37 in the electrode plate support 38. Moreover, the gas introducing shower head 36 has therein a plurality of gas holes 43 that communicate the buffer chamber 37 to the processing space S. A processing gas supplied from the processing gas introducing pipe 42 into the buffer chamber 37 is supplied by the gas introducing shower head 36 into the processing space S via the gas holes 43.

A transfer port 44 for the wafers W is provided in a side wall of the substrate processing chamber 11 in a position at the height of a wafer W that has been lifted up from the susceptor 12 by the pusher pins 35. A gate valve 45 for opening and closing the transfer port 44 is provided in the transfer port 44.

In the substrate processing chamber 11 of the plasma processing apparatus 10, the conductor portion 29 of the susceptor 12 applies radio frequency electrical power into the processing space S, i.e. the space between the susceptor 12 and the upper electrode plate 39, as described above, whereby the processing gas supplied into the processing space S from the gas introducing shower head 36 is turned into high-density plasma, so that positive ions and radicals are produced. Furthermore, the plasma is kept in a desired state by the upper electrode plate 39 applying a DC voltage into the processing space S. The wafer W is subjected to the RIE processing by the positive ions and radicals.

Prior to the present invention, for a conventional plasma processing apparatus 46 as described below, the present inventors observed the state of attachment of deposit in the substrate processing chamber 11 in the case of supplying only radio frequency electrical power of a relatively high frequency to an RF electrode.

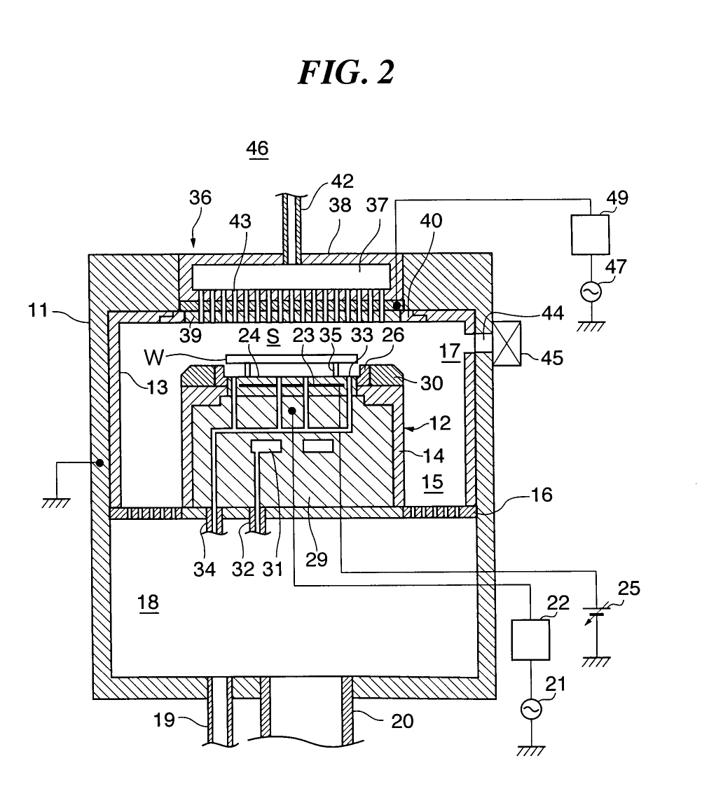

FIG. 2 is a sectional view schematically showing the construction of the conventional plasma processing apparatus. The conventional plasma processing apparatus has basically the same construction and operation as the plasma processing apparatus 10 described above, the only differences to the plasma processing apparatus 10 being that radio frequency electrical power is supplied to the upper electrode plate 39, and the insulator ring 28 and the silicon electrode 27 are absent. Features of the construction and operation that are the same as for the plasma processing apparatus 10 will thus not be described, only features of the construction and operation that are different to for the plasma processing apparatus 10 being described below.

As shown in FIG. 2, the plasma processing apparatus 46 has a radio frequency power source 47 connected to the upper electrode plate 39 via a matcher 49. The upper electrode plate 39 thus applies radio frequency electrical power into the processing space S. Moreover, an annular cover ring 48 made of quartz is disposed surrounding the focus ring 26 on the susceptor 12 such as to be adjacent to the focus ring 26. The focus ring 26 and the cover ring 48 contact one another directly.

For the plasma processing apparatus 46, the present inventors measured the deposit attachment rate (depo rate) in the vicinity of the upper electrode plate 39, specifically at portions of the shield ring 40 and of the side wall member 13 adjacent to the shield ring 40, in the case of supplying 60 MHz radio frequency electrical power at 2200 W from the radio frequency power source 47 to the upper electrode plate 39, without supplying radio frequency electrical power from the radio frequency power source 21 to the conductor portion 29 of the susceptor 12. Here, for the plasma processing apparatus 46, the pressure in the processing space S was set to 2.67 Pa (20 mTorr), C₄F₈ gas and Ar gas were supplied into the processing space S with the flow rates thereof set to 14 sccm and 700 sccm respectively, and plasma was produced. The RIE processing was continued for 5 minutes.

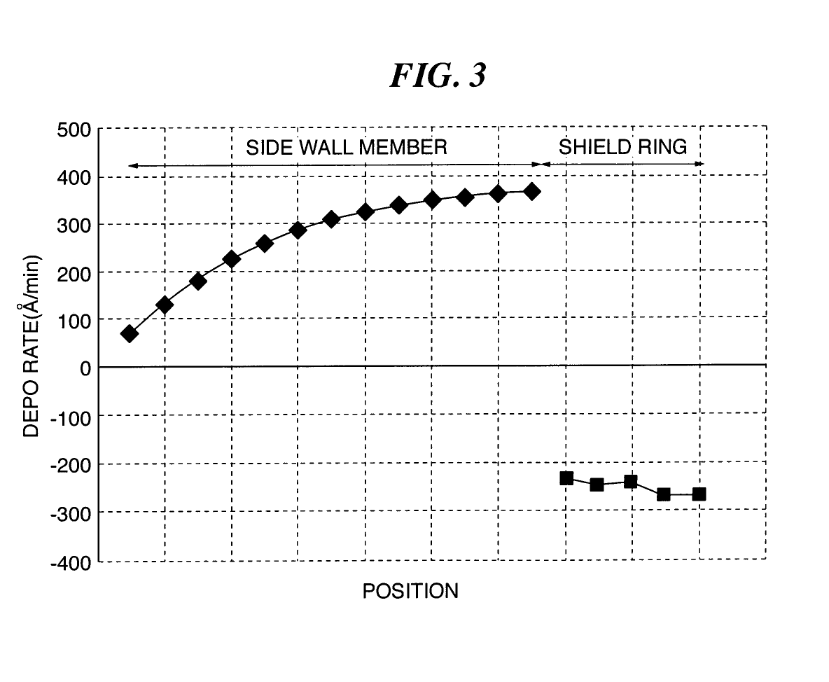

FIG. 3 is a graph showing the relationship between the depo rate and locations on the components in the case of supplying only 60 MHz radio frequency electrical power to the upper electrode plate. In this graph, the axis of abscissas shows the relative position on the respective component relative to the upper electrode plate 39, being closer to the upper electrode plate 39 the further to the right of the graph.

As shown by the graph in FIG. 3, it was found that the depo rate is positive for the side wall member 13, deposit being progressively attached to the side wall member 13, whereas the depo rate is negative for the shield ring 40, the deposit film being progressively removed from the shield ring 40.

For the plasma processing apparatus 46, radio frequency electrical power of a frequency followable by ions, for example 2 MHz, is not supplied to the upper electrode plate 39 or to the conductor portion 29 of the susceptor 12, and moreover the shield ring 40 is made of an insulating material. As a result, a fluctuating potential is not produced on the surface of the shield ring 40, and hence the deposit film is not removed through ions being drawn in (sputtering) due to such a fluctuating potential.

Next, to look into the mechanism of the removal of the deposit film from the shield ring 40, the present inventors calculated through simulation the electric field strength at portions of the processing space S facing portions of the shield ring 40 and the side wall member 13 in the case of supplying the 60 MHz radio frequency electrical power to the upper electrode plate 39. In the following, the electric field at such facing portions of the processing space S is referred to merely as the “facing electric field”.

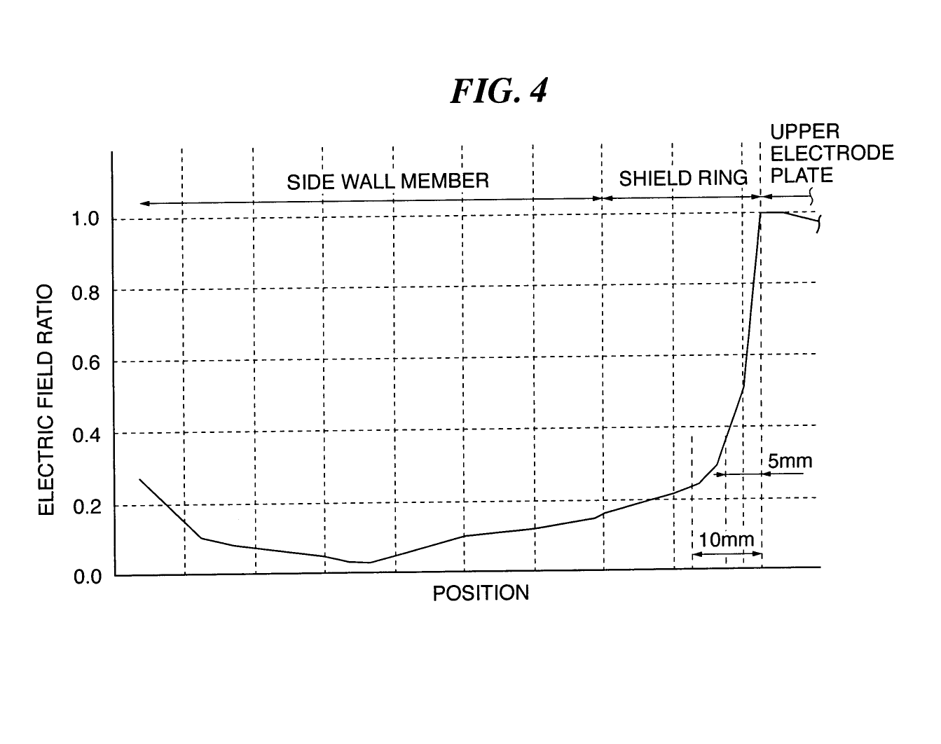

FIG. 4 is a graph showing the relationship between the electric field strength calculated through the simulation and locations on the components in the case of supplying only the 60 MHz radio frequency electrical power to the upper electrode plate. In this graph, again, the axis of abscissas shows the relative position on the respective component relative to the upper electrode plate 39, being closer to the upper electrode plate 39 the further to the right of the graph. Moreover, the axis of ordinates shows the strength ratio, taking the strength of the facing electric field at the peripheral portion of the upper electrode plate 39 to be “1”.

As shown by the graph in FIG. 4, it was found that the strength of the facing electric field at the side wall member 13 adjacent to the shield ring 40 is substantially zero, whereas the strength of the facing electric field over a 10 mm region of the shield ring 40 from the upper electrode plate 39 is more than 20% of the strength of the facing electric field at the peripheral portion of the upper electrode plate 39, and in particular the strength of the facing electric field over a 5 mm region of the shield ring 40 from the upper electrode plate 39 is more than 40% of the strength of the facing electric field at the peripheral portion of the upper electrode plate 39. Moreover, for a region of the shield ring 40 more than 10 mm from the upper electrode plate 39, the facing electric field almost dies out.

From the results of the above simulation, the present inventors obtained the following knowledge regarding the mechanism of the removal of the deposit film from the shield ring 40.

That is, upon the upper electrode plate 39 applying the 60 MHz radio frequency electrical power into the processing space S, a facing electric field facing the upper electrode plate 39 is produced; the radio frequency electrical power not only produces a facing electric field in the portion of the processing space S facing the upper electrode plate 39, but also produces a facing electric field somewhat weaker than the facing electric field facing the upper electrode plate 39 in a portion of the processing space S in the vicinity of the upper electrode plate 39, i.e. facing the shield ring 40 (electric field leakage effect). Ions having an energy in accordance with the potential difference for the facing electric field facing the shield ring 40 thus collide with the shield ring 40, whereby the deposit film is removed from the shield ring 40 through the collisions with the ions.

In the present embodiment, to remove the insulating film formed on the exposed portion of the silicon electrode 27 which is at the ground potential, the electric field leakage effect described above is used. Specifically, the distance between the silicon electrode 27 and the focus ring 26 to which the 40 MHz radio frequency electrical power is transmitted is set in a range of 0.5 to 10 mm, preferably 0.5 to 5 mm. In this case, due to the electric field leakage effect for the 40 MHz radio frequency electrical power applied into the processing space S by the focus ring 26, a facing electric field somewhat weaker than the facing electric field facing the focus ring 26, specifically an electric field having a strength more than 20% of the strength of the facing electric field facing the peripheral portion of the focus ring 26, arises in the portion of the processing space S facing the silicon electrode 27. Ions having an energy in accordance with the potential difference for the facing electric field facing the silicon electrode 27 thus collide with the silicon electrode 27, whereby the insulating film is removed from the silicon electrode 27 through the collisions with the ions. Note that in the case that the silicon electrode 27 is disposed within 0.5 mm from the focus ring 26, instead of disposing the insulator ring 28 between the silicon electrode 27 and the focus ring 26, a vacuum space (spatial capacitor) is formed between the silicon electrode 27 and the focus ring 26. Note also that so long as insulation is possible, the distance between the silicon electrode 27 and the focus ring 26 may in theory even be 0 mm.

According to the plasma processing apparatus 10, the silicon electrode 27, which is a grounding electrode having an exposed portion exposed to the processing space into which a DC voltage is applied is adjacent, with the insulating insulator ring 28 therebetween, to the focus ring 26 which applies 40 MHz radio frequency electrical power into the processing space S, the distance between the silicon electrode 27 and the focus ring 26 being set in a range of 0.5 to 10 mm, preferably 0.5 to 5 mm. Ions will not follow a fluctuating potential produced due to the 40 MHz radio frequency electrical power, and hence an insulating film on the silicon electrode 27 cannot be removed through ions being drawn in thereto due to such a fluctuating potential. However, in a portion of the processing space S facing the silicon electrode 27 there arises an electric field having a strength more than 20% of the strength of the facing electric field facing the peripheral portion of the focus ring 26, and hence ions collide with the silicon electrode 27 due to the potential difference for the electric field. As a result, the insulating film on the silicon electrode 27 can be removed in the plasma processing apparatus 10. That is, the insulating film on the silicon electrode 27 can be removed without supplying radio frequency electrical power of a frequency followable by ions, i.e. not more than 3 MHz, to the conductor portion 29.

In the plasma processing apparatus 10, the insulator ring 28 is made of quartz, and hence radio frequency electrical power can be reliably prevented from being applied to the silicon electrode 27. As a result, the silicon electrode 27 can be kept at the ground potential, and hence a DC voltage can be reliably applied into the processing space S. Instead of disposing the insulator ring 28 between the focus ring 26 and the silicon electrode 27, a vacuum space may be provided between the focus ring 26 and the silicon electrode 27. In this case, radio frequency electrical power can again be reliably prevented from being applied to the silicon electrode 27

In the plasma processing apparatus 10, the frequency of the radio frequency electrical power supplied to the conductor portion 29 of the susceptor 12 (and to the focus ring 26) is 40 MHz. However, this frequency may be any frequency not less than 13 MHz. In this case, although ions cannot follow a fluctuating potential produced due to the radio frequency electrical power of frequency not less than 13 MHz, a facing electric field again arises due to the electric field leakage effect in the portion of the processing space S facing the silicon electrode 27, and hence ions can be reliably drawn onto the silicon electrode 27 by the electric field.

Moreover, in the plasma processing apparatus 10, only the radio frequency power source 21 is connected to the conductor portion 29 of the susceptor 12. However, a plurality of radio frequency power sources may be connected to the conductor portion 29. If one of the radio frequency power sources supplies radio frequency electrical power of a frequency followable by ions, i.e. not more than 3 MHz, that not only will ions collide with the silicon electrode 27 due to the facing electric field produced through the electric field leakage effect, but moreover ions will be drawn onto the silicon electrode 27 due to a fluctuating potential of the frequency followable by ions, and hence the insulating film on the silicon electrode 27 can be removed yet more reliably.

Next, a plasma processing apparatus according to a second embodiment of the present invention will be described.

For the present embodiment, the construction and operation are basically the same as for the first embodiment described above, the only differences to the first embodiment being that radio frequency electrical power is supplied to the upper electrode plate, a silicon electrode at the ground potential is disposed in the vicinity of the upper electrode plate, and an insulator ring and silicon electrode are not disposed surrounding the focus ring. Features of the construction and operation that are the same as in the first embodiment will thus not be described, only features of the construction and operation that are different to in the first embodiment being described below.

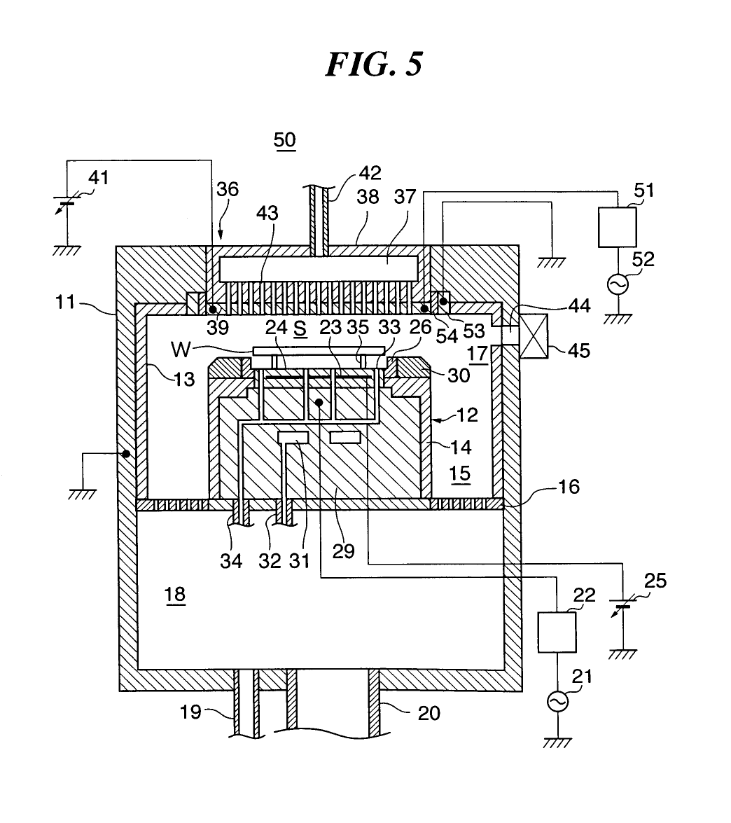

FIG. 5 is a sectional view schematically showing the construction of the plasma processing apparatus according to the present embodiment.

As shown in FIG. 5, the plasma processing apparatus 50 has a radio frequency power source 52 connected to the upper electrode plate 39 via a matcher 51. The radio frequency power source 52 supplies radio frequency electrical power of a relatively high frequency, for example 60 MHz, to the upper electrode plate 39. The upper electrode plate 39 thus acts as an RF electrode, applying the 60 MHz radio frequency electrical power into the processing space S. Moreover, the upper electrode plate 39 is also electrically connected to the DC power source 41, and thus applies a DC voltage into the processing space S.

An annular silicon electrode 53 made of silicon is disposed surrounding the upper electrode plate 39 adjacent to the upper electrode plate 39. The silicon electrode 53 has an exposed portion that is exposed to the processing space S, and moreover is electrically grounded and thus acts as a grounding electrode. Moreover, the silicon electrode 53 constitutes part of a path of a DC current due to the DC voltage applied into the processing space S by the upper electrode plate 39.

An annular shield ring 54 (insulating portion) made of an insulating material, for example quartz (Qz), is disposed between the upper electrode plate 39 and the silicon electrode 53. The silicon electrode 53 is thus electrically insulated from the upper electrode plate 39, the shield ring 54 reliably preventing the radio frequency electrical power supplied to the upper electrode plate 39 from being applied to the silicon electrode 53.

In the plasma processing apparatus 50, the radio frequency power source 21 supplies radio frequency electrical power of a relatively low frequency, for example 2 MHz, to the conductor portion 29 of the susceptor 12. Furthermore, an annular cover ring 48 made of quartz is disposed surrounding the focus ring 26 on the susceptor 12 such as to be adjacent to the focus ring 26. The focus ring 26 and the cover ring 48 contact one another directly.

In the plasma processing apparatus 50, the distance between the silicon electrode 53 and the upper electrode plate 39 is set in a range of 0.5 to 10 mm, preferably 0.5 to 5 mm. In this case, due to an electric field leakage effect for the 60 MHz radio frequency electrical power applied into the processing space S by the upper electrode plate 39, a facing electric field somewhat weaker than the facing electric field facing the upper electrode plate 39 arises in a portion of the processing space S facing the silicon electrode 53. Ions having an energy in accordance with the potential difference for the facing electric field facing the silicon electrode 53 thus collide with the silicon electrode 53, whereby an insulating film can be removed from the silicon electrode 53 through the collisions with the ions. Moreover, the 2 MHz radio frequency electrical power is transmitted from the conductor portion 29 of the susceptor 12 to the silicon electrode 53, and hence a fluctuating potential that fluctuates at 2 MHz is produced on the exposed portion of the silicon electrode 53. Ions are drawn onto the silicon electrode 53 through the fluctuating potential, and hence the insulating film can be reliably removed from the silicon electrode 53 in the plasma processing apparatus 50.

In the plasma processing apparatus 50 described above, the radio frequency power source 21 supplies 2 MHz radio frequency electrical power to the conductor portion 29 of the susceptor 12. However, radio frequency electrical power need not be supplied to the conductor portion 29. Even in this case, due to the electric field leakage effect for the 60 MHz radio frequency electrical power applied into the processing space S by the upper electrode plate 39, a facing electric field facing the silicon electrode 53 arises, and hence the insulating film on the silicon electrode 53 can be removed.

Note also that the substrates subjected to the RIE processing in the plasma processing apparatus 10 or 50 are not limited to being semiconductor wafers for semiconductor devices, but rather may instead be any of various substrates used in LCDs (liquid crystal displays), FPDs (flat panel displays) or the like, photomasks, CD substrates, printed substrates, or the like.

The above-described embodiments are merely exemplary of the present invention, and are not be construed to limit the scope of the present invention.

The scope of the present invention is defined by the scope of the appended claims, and is not limited to only the specific descriptions in this specification. Furthermore, all modifications and changes belonging to equivalents of the claims are considered to fall within the scope of the present invention.

What is claimed is:

1. A plasma processing apparatus that has a substrate processing chamber having therein a processing space in which plasma processing is carried out on a substrate, an RF electrode that applies radio frequency electrical power into said processing space, a DC electrode that applies a DC voltage into said processing space, and a grounding electrode that is exposed to said processing space, wherein
said grounding electrode and said RF electrode are adjacent to one another with an insulating portion therebetween, and
a distance between said grounding electrode and said RF electrode is set in a range of 0 to 10 mm.

2. A plasma processing apparatus as claimed in claim 1, wherein the distance is set in a range of 0 to 5 mm.

3. A plasma processing apparatus as claimed in claim 1, wherein a lower limit of the distance is 0.5 mm.

4. A plasma processing apparatus as claimed in claim 1, wherein said insulating portion comprises an insulator or a vacuum space.

5. A plasma processing apparatus that has a substrate processing chamber having therein a processing space in which plasma processing is carried out on a substrate, an RF electrode that applies only radio frequency electrical power of not less than a predetermined frequency into said processing space, a DC electrode that applies a DC voltage into said processing space, and a grounding electrode that is exposed to said processing space, wherein
said grounding electrode and said RF electrode are adjacent to one another with an insulating portion therebetween.

6. A plasma processing apparatus as claimed in claim 5, wherein the predetermined frequency is 13 MHz.

7. A plasma processing apparatus as claimed in claim 5, wherein said insulating portion comprises an insulator or a vacuum space.
